(19) United States
(12) Patent Application Publication
(10) Pub. No.: US 2025/0293003 A1
(43) Pub. Date: Sep. 18, 2025

(54) SILICON MEMBER AND SILICON MEMBER PRODUCTION METHOD

(71) Applicant: MITSUBISHI MATERIALS CORPORATION, Tokyo (JP)

(72) Inventors: Shinji Kato, Sanda-shi (JP); Hiromichi Matsuda, Sanda-shi (JP)

(73) Assignee: MITSUBISHI MATERIALS CORPORATION, Tokyo (JP)

(21) Appl. No.: 18/858,894

(22) PCT Filed: Mar. 30, 2023
(86) PCT No.: PCT/JP2023/013106

§ 371 Date: Oct. 22, 2024

(30) Foreign Application Priority Data
Apr. 27, 2022 (JP) 2022-073579

(51) Int. Cl. H01J 37/32; B32B 9/04; C22C 21/02

(52) U.S. Cl. CPC H01J 37/32495; B32B 9/041; C22C 21/02; B32B 2311/24

(57) ABSTRACT

This silicon member includes a plurality of plate-shaped members consisting of a Si-containing material, the plate-shaped members are bonded in a thickness direction, a bonding layer is formed between the plate-shaped members, and an area ratio of Si phases in the bonding layer is 12% or less. An aspect ratio of the Si phase in the bonding layer is preferably 3.0 or less.

### TECHNICAL FIELD

The present invention relates to a silicon member used in, for example, a plasma processing apparatus, and a method for producing a silicon member.

The present application claims priority on Japanese Patent Application No. 2022-073579 filed on Apr. 27, 2022, the content of which is incorporated herein by reference.

### BACKGROUND ART

In the related art, in plasma processing apparatuses such as plasma etching apparatuses and plasma CVD apparatuses used in, for example, semiconductor device production processes, an electrode plate connected to a high-frequency power source and a stand are arranged in the chamber of the various apparatuses to, for example, vertically oppose each other and a silicon wafer is placed on the stand. In this state, plasma is generated by applying a high-frequency voltage while circulating gas from through holes formed in the electrode plate toward the silicon wafer and processes such as etching are performed on the silicon wafer.

In the above-described plasma processing apparatuses and the like, silicon members such as silicon, silicon nitride, and silicon carbide are widely used to suppress metal contamination in the chamber.

For example, a silicon member having a structure in which a plurality of air holes are formed in a silicon plate material is used as an electrode plate used in a plasma processing apparatus.

Silicon members disposed in the chamber of a plasma processing apparatus or the like gradually wear out with use. Therefore, there is a demand for bonding other silicon members to worn-out silicon members and reusing the obtained silicon bonded bodies as silicon members.

For example, Patent Document 1 discloses a silicon electrode plate in which a plurality of plate-shaped electrode members made of silicon are bonded in a thickness direction.

In Patent Document 1, an Al foil is interposed between plate-shaped electrode members and heat-treated at 800° C. to form a bonding part consisting of an Al—Si eutectic alloy and bond the plate-shaped electrode members together (refer to paragraphs 0018 to 0026 of Patent Document 1).

### CITATION LIST

### Patent Document

Patent Document 1: Japanese Patent No. 6146840

### SUMMARY OF INVENTION

### Technical Problem

Also, in the silicon electrode plate disclosed in Patent Document 1, the bonding part consists of a eutectic alloy with silicon (for example, an Al—Si eutectic alloy, or the like), thus, there is a large amount of Si phases in the bonding part, there is a concern that the Si phase in the bonding part might become the starting point of fracturing and cause cracks in the bonding part when used in a high-temperature environment, and the heat resistance is insufficient. In addition, there is a concern that voids and shrink holes might occur in the bonding part and the bonding strength lowers.

The present invention was made in consideration of the above-described circumstances and has an objective of providing a silicon member that has a sufficiently high bonding strength, excellent heat resistance, and is able to be used stably even in a high-temperature environment, and a method for producing this silicon member.

### Solution to Problem

In order to solve the above-described problem, the silicon member of a first aspect of the present invention includes a plurality of plate-shaped members consisting of a Si-containing material, in which the plate-shaped members are bonded in a thickness direction, a bonding layer is formed between the plate-shaped members, and an area ratio of Si phases in the bonding layer is 12% or less.

According to the silicon member of the first aspect of the present invention, since the area ratio of the Si phases in the bonding layer formed between the plate-shaped members is 12% or less, the formation of a coarse Si phase in the bonding layer is suppressed, it is possible to suppress damage to the bonding layer even when used in a high-temperature environment, and the heat resistance is excellent. In addition, the bonding layer does not have a large number of shrink holes or voids and the bonding strength is excellent.

A second aspect of the present invention is the silicon member of the first aspect of the present invention, in which an aspect ratio of the Si phase in the bonding layer is 3.0 or less.

According to the silicon member of the second aspect of the present invention, since the aspect ratio of the Si phase in the bonding layer is 3.0 or less, it is possible to suppress damage to the bonding layer even when used in a high-temperature environment and the heat resistance is particularly excellent.

A third aspect of the present invention is the silicon member of the first aspect or second aspect of the present invention, in which the bonding layer includes Al or a metal containing Al.

According to the silicon member of the third aspect of the present invention, since the bonding layer includes Al or a metal containing Al, it is possible to reliably bond a plurality of plate-shaped members consisting of a Si-containing material in the thickness direction.

A fourth aspect of the present invention is the silicon member of the third aspect of the present invention, in which the bonding layer consists of an Al—Si alloy in which an amount of Si is in a range of 0.5 mass % or more and 12.6 mass % or less.

According to the silicon member of the fourth aspect of the present invention, since the bonding layer consists of an Al—Si alloy in which an amount of Si is in a range of 0.5 mass % or more and 12.6 mass % or less, it is possible to reliably bond a plurality of plate-shaped members consisting of a Si-containing material in the thickness direction. In addition, since the area ratio of the Si phases in the bonding layer is suppressed to 12% or less, it is possible to suppress damage to the bonding layer even when used in a high-temperature environment and the heat resistance is particularly excellent.

A fifth aspect of the present invention is the silicon member of the third aspect or fourth aspect of the present invention, in which, when line analysis is performed along a virtual line extending in the thickness direction of the silicon member, a number of intersections between Si peaks and Al peaks on the virtual line is 4 or less in the bonding layer.

According to the silicon member of the fifth aspect of the present invention, since the number of intersections between Si peaks and Al peaks on the virtual line is 4 or less in the bonding layer when the line analysis is performed along the virtual line extending in the thickness direction of the silicon member, the number of Si phases present in the bonding layer is small, it is possible to suppress damage to the bonding layer even when used in a high-temperature environment, and the heat resistance is particularly excellent.

A method for producing a silicon member of a sixth aspect of the present invention is a method for producing the silicon member according to any one of the first aspect to fifth aspect of the present invention, the method including: a laminating step of arranging a bonding material between a plurality of the plate-shaped members and forming a laminate of the plurality of the plate-shaped members and the bonding material; and a pressing and heating step of heating the laminate to a temperature lower than a liquidus temperature of the bonding material while pressing the laminate in a lamination direction.

According to the method for producing a silicon member of the sixth aspect of the present invention, since the pressing and heating step is configured to carry out the heating to a temperature lower than the liquidus temperature of the bonding material, it is possible to suppress the area ratio of the Si phases in the bonding layer to 12% or less. Therefore, it is possible to suppress the formation of a coarse Si phase in the bonding layer and to produce a silicon member having excellent heat resistance.

In addition, the pressing and heating step produces almost no liquid phase, it is possible to suppress the protrusion of the bonding material, shrink holes and voids are not formed in the bonding layer, and it is possible to improve the bonding strength.

The method for producing a silicon member production of a seventh aspect of the present invention is the method for producing a silicon member of the sixth aspect of the present invention, in which the bonding material includes Al or a metal containing Al.

According to the method for producing a silicon member of the seventh aspect of the present invention, since the bonding material includes Al or a metal containing Al, it is possible to reliably bond a plurality of plate-shaped members consisting of a Si-containing material.

The method for producing a silicon member of an eighth aspect of the present invention is the method for producing a silicon member of the seventh aspect of the present invention, in which the bonding material consists of an Al—Si alloy in which an amount of Si is in a range of 0.5 mass % or more and 12.6 mass % or less.

According to the method for producing a silicon member of the eighth aspect of the present invention, since the bonding material consists of an Al—Si alloy in which an amount of Si is in a range of 0.5 mass % or more and 12.6 mass % or less, it is possible to suppress the diffusion of Si from the plate-shaped members to the bonding layer and it is possible to sufficiently lower the area ratio of the Si phases in the bonding layer.

The method for producing a silicon member of a ninth aspect of the present invention is the method for producing a silicon member of any one of the sixth aspect to eighth aspect of the present invention, further including, before the laminating step, an Al layer forming step of forming Al layers on bonding surfaces of the plate-shaped members, in which the laminating step includes arranging the plurality of the plate-shaped members such that the Al layers of the plate-shaped members oppose each other, arranging the bonding material to contact the opposing Al layers, and forming the laminate of the plurality of the plate-shaped members and the bonding material.

According to the method for producing a silicon member of the ninth aspect of the present invention, since the method is configured such that an Al layer is formed on the bonding surface of the plate-shaped member, a bonding material is arranged in contact with the Al layer to form a laminate, and the laminate is heated to a temperature lower than the liquidus temperature of the bonding material while pressing the laminate in the lamination direction, the diffusion of Si from the plate-shaped member to the bonding material is suppressed by the Al layer. Therefore, it is possible to suppress the formation of a coarse Si phase in the bonding layer and it is possible to produce a silicon member having excellent heat resistance.

### Advantageous Effects of Invention

According to the aspects of the present invention, it is possible to provide a silicon member that has a sufficiently high bonding strength, excellent heat resistance, and is able to be used stably even in a high-temperature environment, and a method for producing the silicon member.

### BRIEF DESCRIPTION OF DRAWINGS

FIG. 1A an explanatory diagram showing an example of a silicon member according to one embodiment of the present invention, which is a perspective view of the silicon member.

FIG. 1B an explanatory diagram showing an example of a silicon member according to one embodiment of the present invention, which is an enlarged explanatory diagram of a bonding layer.

FIG. 2 an explanatory diagram of boundary points between Si phases and an Al phase that are present on virtual lines extending in the thickness direction of the bonding layer of a silicon member according to one embodiment of the present invention.

FIG. 3 a flow diagram showing a method for producing a silicon member according to one embodiment of the present invention.

FIG. 4 an explanatory diagram showing a method for producing a silicon member according to one embodiment of the present invention.

FIG. 5A an observation photograph of a bonding layer of a silicon member of Invention Example 1, which is an SEM image.

FIG. 5B an observation photograph of the bonding layer of the silicon member of Invention Example 1, which is an Al mapping result.

FIG. 5C an observation photograph of the bonding layer of the silicon member of Invention Example 1, which is a Si mapping result.

FIG. 6A an observation photograph of a bonding layer of a silicon member of Invention Example 6, which is an SEM image.

FIG. 6B an observation photograph of the bonding layer of the silicon member of Invention Example 6, which is a line analysis result of Al and Si.

FIG. 6C an observation photograph of the bonding layer of the silicon member of Invention Example 6, which is an Al mapping result.

FIG. 6D an observation photograph of the bonding layer of the silicon member of Invention Example 6, which is a Si mapping result.

FIG. 7A an observation photograph of a bonding layer of a silicon member of Comparative Example 1, which is an SEM image.

FIG. 7B an observation photograph of the bonding layer of the silicon member of Comparative Example 1, which is a line analysis result of Al and Si.

FIG. 7C an observation photograph of the bonding layer of the silicon member of Comparative Example 1, which is an Al mapping result.

FIG. 7D an observation photograph of the bonding layer of the silicon member of Comparative Example 1, which is a Si mapping result.

FIG. 8A a schematic explanatory diagram of the tensile test in the Examples, which is a diagram showing a test piece.

FIG. 8B a schematic explanatory diagram of the tensile test in the Examples, which is a diagram showing a test piece and a tensile test jig.

FIG. 8C a schematic explanatory diagram of the tensile test in the Examples, which is a diagram showing a tensile testing machine.

### DESCRIPTION OF EMBODIMENTS

A description will be given below of a silicon member and a method for producing a silicon member, which are embodiments of the present invention.

The silicon member of the present embodiment is, for example, a silicon member disposed in a chamber in a plasma processing apparatus such as a plasma etching apparatus or a plasma CVD apparatus used in a semiconductor device production process and, in the present embodiment, the silicon member is a silicon electrode plate having a structure in which a plurality of air holes are formed in a silicon plate material. That is, in the silicon member of the present embodiment, a plurality of silicon electrode plates worn out through use are bonded together and used as a regenerated silicon electrode plate.

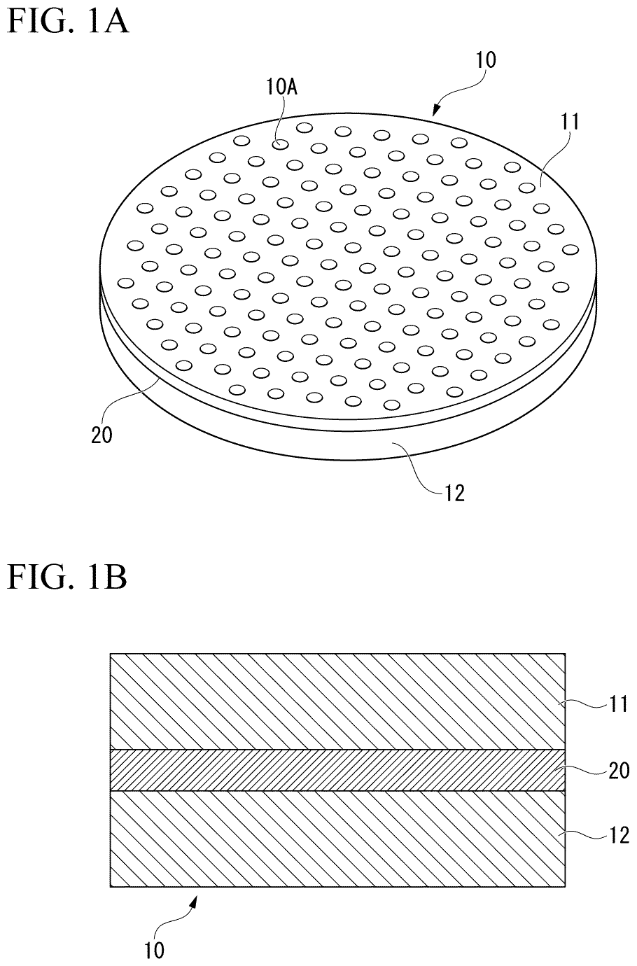

A silicon member 10 (regenerated silicon electrode plate) of the present embodiment is provided with a plurality of air holes 10A penetrating in the thickness direction, as shown in FIG. 1A.

The silicon member 10 of the present embodiment has a structure in which a first plate-shaped member 11 and a second plate-shaped member 12 are bonded in the thickness direction, as shown in FIG. 1A and FIG. 1B, and a bonding layer 20 is formed between the first plate-shaped member 11 and the second plate-shaped member 12.

The first plate-shaped member 11 and the second plate-shaped member 12, for example, consist of a Si-containing material such as silicon, silicon nitride, and silicon carbide.

The area ratio of Si phases 25 in the bonding layer 20 formed between the first plate-shaped member 11 and the second plate-shaped member 12 is 12% or less.

The area ratio of the Si phases 25 in the bonding layer 20 is more preferably 10% or less and even more preferably 8% or less. The lower limit value of the area ratio of the Si phases 25 in the bonding layer 20 is not particularly limited, but is preferably 0% or more.

In the present embodiment, the area ratio of the Si phases 25 in the bonding layer 20 is the area ratio in the cross-section of the bonding layer 20 along the lamination direction of the silicon member 10.

In addition, in the present embodiment, the aspect ratio of the Si phase 25 in the bonding layer 20 is preferably 3.0 or less.

The aspect ratio of the Si phase 25 in the bonding layer 20 is more preferably 2.5 or less. The lower limit value of the aspect ratio of the Si phase 25 in the bonding layer 20 is not particularly limited, but is preferably 1.0 or more. The shape of the Si phase 25 in the bonding layer 20 is preferably spherical.

In addition, in the present embodiment, the bonding layer 20 preferably includes Al or a metal containing Al.

The bonding layer 20 is preferably an Al—Si alloy in which an amount of Si is in a range of 0.5 mass % or more and 12.6 mass % or less. Furthermore, the bonding layer 20 is more preferably an Al—Si alloy in which an amount of Si is in the range of 0.5 mass % or more and 8.0 mass % or less.

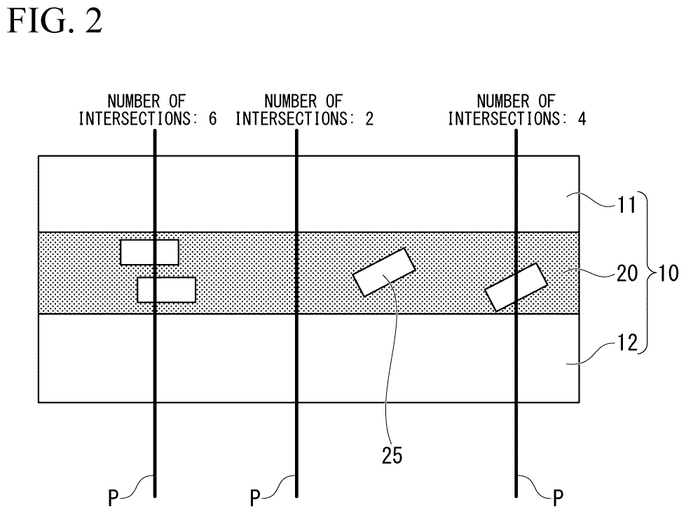

In addition, in the present embodiment, in a case where the bonding layer 20 includes Al or a metal containing Al, as shown in FIG. 2, when line analysis is performed along a virtual line P extending in the thickness direction of the silicon member 10, the number of intersections between the Si peaks and the Al peaks on the virtual line Pis preferably 4 or less in the bonding layer 20.

At this time, as shown in FIG. 2, the Si peaks indicate the Si phase 25 in the first plate-shaped member 11, the second plate-shaped member 12, and the bonding layer 20. In addition, the Al peaks indicate the bonding layer 20 including Al or a metal containing Al.

Therefore, the boundary between the first plate-shaped member 11 and the bonding layer 20 and the boundary between the second plate-shaped member 12 and the bonding layer 20 also become intersections between the Si peaks and the Al peaks in the bonding layer 20.

The lower limit value of the number of intersections between the Si peaks and the Al peaks on the virtual line P is not particularly limited, but is preferably 2 or more.

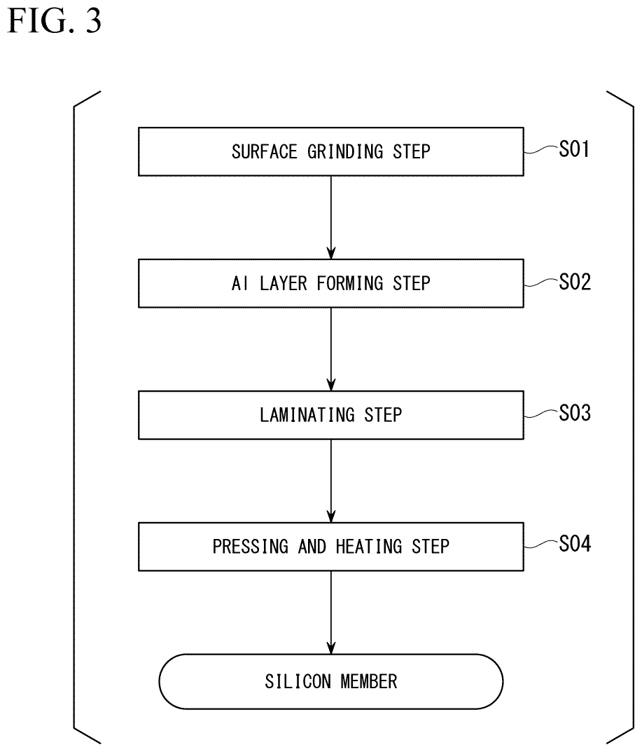

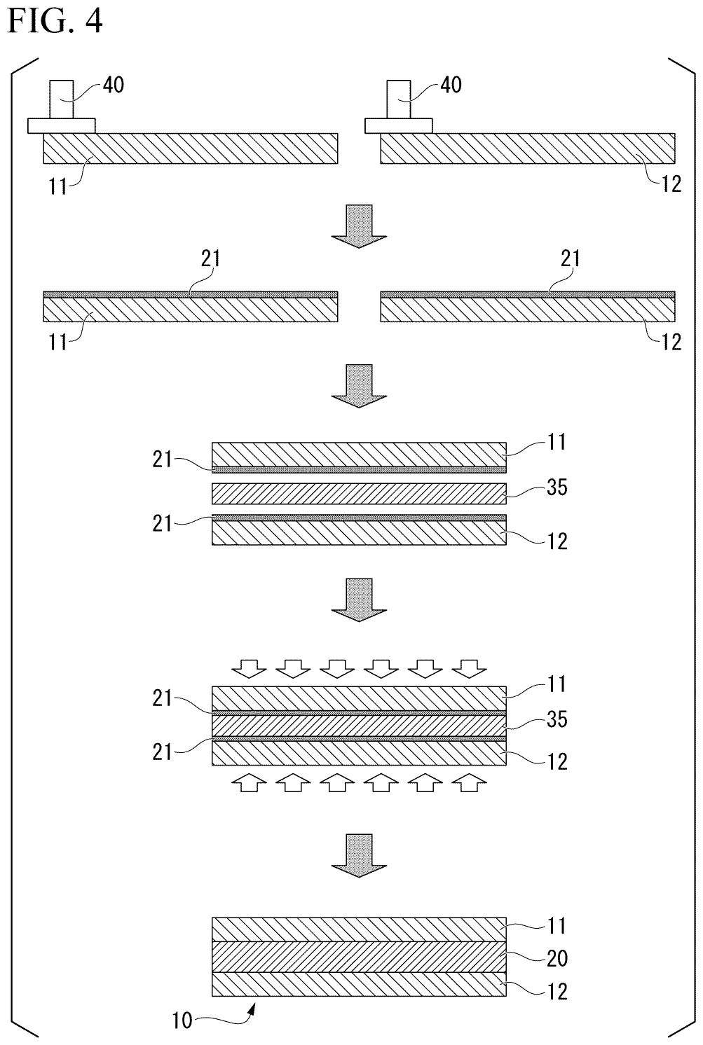

Next, a description will be given of the method for producing the silicon member 10 of the present embodiment with reference to FIG. 3 and FIG. 4.

As shown in FIG. 3 and FIG. 4, the method for producing the silicon member 10 of the present embodiment includes: a surface grinding step S01 of grinding the surfaces of the first plate-shaped member 11 and the second plate-shaped member 12, which are used silicon electrode plates; an Al layer forming step S02 of forming an Al layer 21 on each of the bonding surfaces of the first plate-shaped member 11 and the second plate-shaped member 12; a laminating step S03 of forming a laminate of the first plate-shaped member 11, a bonding material 35, and the second plate-shaped member 12; and a pressing and heating step S04 of heating the laminate while pressing the laminate in the lamination direction.

A detailed description will be given below of each step of the method for producing the silicon member 10 of the present embodiment.

### (Surface Grinding Step S01)

In the present embodiment, as shown in FIG. 4, two used silicon electrode plates are prepared.

The surfaces (plasma surfaces) of the silicon electrode plates are ground by a grinding machine 40. Due to this, the first plate-shaped member 11 and the second plate-shaped member 12 are obtained. The plasma surfaces are ground to remove the plasma surface side portions of the air holes that are enlarged due to wear caused by use.

### (Al Layer Forming Step S02)

Next, the Al layer 21 is formed on each of the bonding surfaces of the first plate-shaped member 11 and the second plate-shaped member 12.

The method for forming the Al layers 21 is not particularly limited and it is possible to appropriately select various existing methods such as a vapor deposition method and a sputtering method. In the present embodiment, the Al layers 21 are formed by a sputtering method using an Al sputtering target.

The thickness of the Al layers 21 is preferably in a range of 0.05 μm or more and 2 μm or less.

### (Laminating Step S03)

Next, the first plate-shaped member 11 and the second plate-shaped member 12 are arranged such that the Al layers 21, 21 thereof oppose each other and the bonding material 35 is arranged to contact the opposing Al layers 21, 21 to form a laminate of the first plate-shaped member 11, the bonding material 35, and the second plate-shaped member 12.

The bonding material 35 preferably includes Al or a metal containing Al. In the present embodiment, it is preferable to use an Al—Si alloy in which an amount of Si is in a range of 0.5 mass % or more and 12.6 mass % or less as the bonding material 35.

### (Pressing and Heating Step S04)

Next, the laminate is heated while being pressed in the lamination direction and the first plate-shaped member 11 and the second plate-shaped member 12 are bonded via the bonding layer 20. The Al layers 21, 21 formed on the bonding surfaces of the first plate-shaped member 11 and the second plate-shaped member 12 are incorporated into the bonding layer 20 during heating in the pressing and heating step S04.

The holding temperature in the pressing and heating step S04 is lower than the melting point of the Al layers 21 or lower than the liquidus temperature of the bonding material 35 to suppress the area ratio of the Si phases in the bonding layer 20 to 12% or less.

In the present embodiment, in a case where Al or an Al—Si alloy in which an amount of Si is in the range of 0 mass % or more and 12.6 mass % or less is used as the bonding material 35, the holding temperature is preferably in the range of 500° C. or higher and 650° C. or lower. In addition, in the present embodiment, in a case where bonding is performed using the Al layers 21 formed on the bonding surfaces of the first plate-shaped member 11 and the second plate-shaped member 12 (in a case where the Al layers 21 are used as the bonding material), the holding temperature is preferably in the range of 500° C. or higher and 650° C. or lower.

In a case where Al or an Al—Si alloy in which an amount of Si is in the range of 0.5 mass % or more and 12.6 mass % or less is used as the bonding material 35, the lower limit of the holding temperature is more preferably 550° C. or more and even more preferably 580° C. or more. In addition, the upper limit of the holding temperature is more preferably 640° C. or lower and even more preferably 600° C. or lower.

In addition, the holding time in the pressing and heating step S04 is preferably in the range of 1 hour or more and 16 hours or less.

The lower limit of the holding time is more preferably 1.5 hours or more and even more preferably 2 hours or more. In addition, the upper limit of the holding time is more preferably 8 hours or less and even more preferably 6 hours or less.

Furthermore, the pressing load in the lamination direction in the pressing and heating step S04 is preferably in the range of 0.01 MPa or more and 10 MPa or less.

The lower limit of the pressing load in the lamination direction is more preferably 0.03 MPa or more and even more preferably 0.1 MPa or more. In addition, the upper limit of the pressing load in the lamination direction is more preferably 8 MPa or less and even more preferably 6 MPa or less.

It is possible to produce the silicon member 10 (regenerated silicon electrode plate) of the present embodiment by the various steps described above.

In the silicon member 10 of the present embodiment formed as described above, the area ratio of the Si phases 25 in the bonding layer 20 formed between the first plate-shaped member 11 and the second plate-shaped member 12 is 12% or less, thus, the formation of the coarse Si phase 25 in the bonding layer 20 is suppressed, it is possible to suppress damage to the bonding layer 20 even when used in a high-temperature environment, and the heat resistance is excellent. In addition, a large amount of liquid phase is not generated during bonding, there are not large numbers of shrink holes or voids in the bonding layer 20, and the bonding strength is excellent.

In the silicon member 10 of the present embodiment, in a case where the aspect ratio of the Si phase 25 in the bonding layer 20 is 3.0 or less, it is possible to suppress damage to the bonding layer 20 from the starting point of the Si phase 25 even when used in a high-temperature environment and the heat resistance is particularly excellent.

In addition, in the silicon member 10 of the present embodiment, in a case where the bonding layer 20 includes Al or a metal containing Al, it is possible to reliably bond the first plate-shaped member 11 and the second plate-shaped member 12 consisting of a Si-containing material in the thickness direction.

Furthermore, in the silicon member 10 of the present embodiment, in a case where the bonding layer 20 consists of an Al—Si alloy in which an amount of Si is in the range of 0.5 mass % or more and 12.6 mass % or less, it is possible to suppress the diffusion of Si from the first plate-shaped member 11 and the second plate-shaped member 12 consisting of a Si-containing material to the bonding layer 20 and it is possible to sufficiently lower the area ratio of the Si phases 25 in the bonding layer 20.

According to the method for producing the silicon member 10 of the present embodiment, since in the pressing and heating step S04, the laminate is heated to a temperature lower than the liquidus temperature of the bonding material 35, a large amount of liquid phase is not generated during bonding and it is possible to suppress the area ratio of the Si phases 25 in the bonding layer 20 to 12% or less. Thus, it is possible to suppress the formation of the coarse Si phase 25 in the bonding layer 20 and it is possible to produce the silicon member 10 having excellent heat resistance.

In addition, a large amount of liquid phase is not generated in the pressing and heating step S04, it is possible to suppress the protrusion of the bonding material 35, shrink holes and voids are not formed in the bonding layer 20, and it is possible to improve the bonding strength.

In the method for producing the silicon member 10 of the present embodiment, in a case where the bonding material 35 includes Al or a metal containing Al, it is possible to reliably bond the first plate-shaped member 11 and the second plate-shaped member 12 which consist of a Si-containing material.

In addition, in the method for producing the silicon member 10 of the present embodiment, the bonding material 35 consists of an Al—Si alloy in which an amount of Si is in a range of 0.5 mass % or more and 12.6 mass % or less, thus, it is possible to sufficiently suppress the diffusion of Si from the first plate-shaped member 11 and the second plate-shaped member 12 to the bonding layer 20 and it is possible to sufficiently lower the area ratio of the Si phases 25 in the bonding layer 20.

Furthermore, in the method for producing the silicon member 10 of the present embodiment, it is preferable to include the Al layer forming step S02 of forming the Al layers 21 on the bonding surfaces of the first plate-shaped member 11 and the second plate-shaped member 12 before the laminating step S03. Furthermore, in the laminating step S03, it is preferable that the first plate-shaped member 11 and the second plate-shaped member 12 are arranged such that the Al layers 21, 21 thereof oppose each other and the bonding material 35 is arranged to contact the opposing Al layers 21, 21 to form a laminate of the first plate-shaped member 11, the bonding material 35, and the second plate-shaped member 12. In this case, it is possible to suppress the formation of the coarse Si phase 25 in the bonding layer 20 and it is possible to produce the silicon member 10 having excellent heat resistance.

A description was given above of embodiments of the present invention, but the present invention is not limited thereto and is able to be appropriately modified without departing from the technical features of the invention.

For example, in the present embodiment, the silicon member was described as a regenerated silicon electrode plate formed by bonding two used silicon electrode plates, but the present invention is not limited thereto and the silicon member may include plate-shaped members which consist of a Si-containing material and are bonded together, and may include three or more plate-shaped members bonded together.

In a case where the silicon member includes three or more plate-shaped members, the number of intersections between the Si peaks and the Al peaks on a virtual line extending in the thickness direction is the number measured in a range of two plate-shaped members and one bonding layer formed therebetween.

In addition, in the present embodiment, a description was given in which Al layers are formed on the bonding surfaces of the first plate-shaped member and the second plate-shaped member, and the first plate-shaped member and the second plate-shaped member are bonded together via a bonding material, but the present invention is not limited thereto and the first plate-shaped member and the second plate-shaped member may be bonded together by disposing a bonding material therebetween without forming Al layers on the bonding surfaces.

### EXAMPLES

A description will be given below of the results of confirmation experiments conducted to confirm the effectiveness of the present invention.

Plate-shaped members (diameter (q) 125 mm×thickness (t) 5 mm) made of silicon were prepared. In Invention Examples 1 to 3, 6, and 7, an Al layer (underlying Al layer) was formed on the bonding surface of the plate-shaped member as shown in Table 1 by sputter deposition using an Al sputtering target. In addition, the bonding materials shown in Table 1 were also prepared.

A laminate was formed in which the prepared plate-shaped member, bonding material, and plate-shaped member were laminated. The two plate-shaped members were bonded by pressing and heating this laminate under the conditions shown in Table 1 and various silicon members having bonding layers were produced.

The obtained silicon members were evaluated as follows. The evaluation results are shown in Table 2.

### (Area Ratio of Si Phases)

Using an SEM-EDS device (an electron scanning microscope on which an energy dispersive X-ray analyzer was mounted), a cross-section along the lamination direction of a silicon member was observed and a mapping analysis of Si and the elements forming the bonding layer (below, bonding layer elements) was performed on the bonding layer in the cross-section at a magnification of 5000 times. For each mapping result, a semi-quantitative calculation was performed for each pixel using the quantitative map function of the software installed in the SEM-EDS device, assuming that only Si and bonding layer elements were present, and a quantitative map was created showing the amount (weight %) of each pixel. Based on the created quantitative map, the phase in which an amount of Si was of 99 mass % or more in the bonding layer within the field of view was set as the Si phase and the area ratio of the Si phases in the bonding layer within the field of view was calculated.

The area ratio of the Si phases within the outline of the bonding layer in the field of view was calculated. A plurality of fields of view, that were three fields of view (three images), were used for the calculation and the area ratio was the average value in three fields of view (three images). The observation magnification may be selected such that the upper and lower interfaces of the bonding layer are within the field of view.

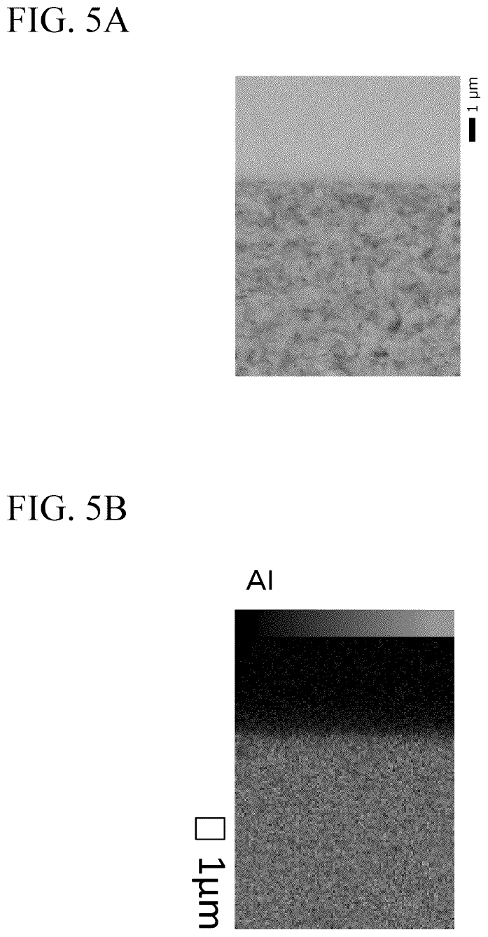

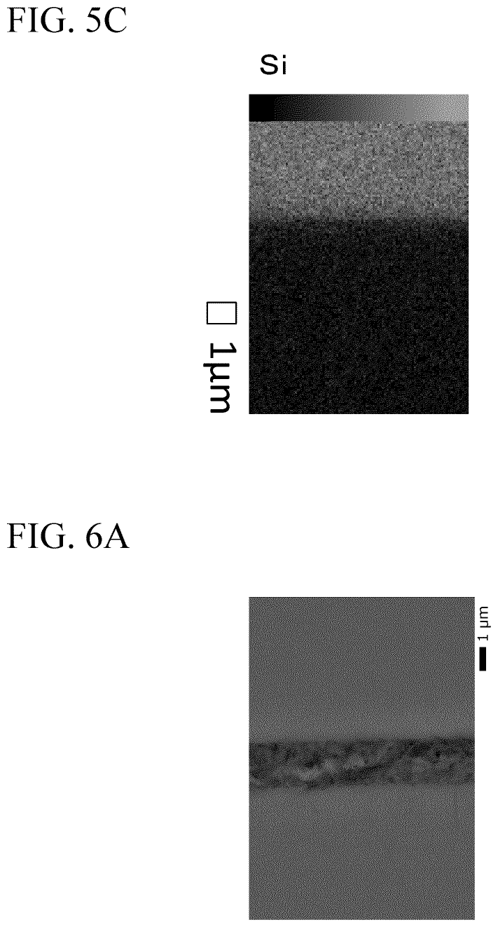

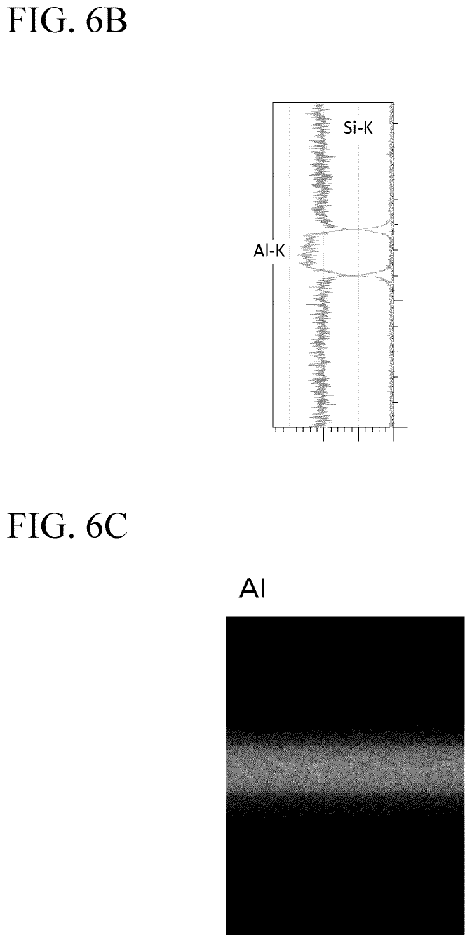

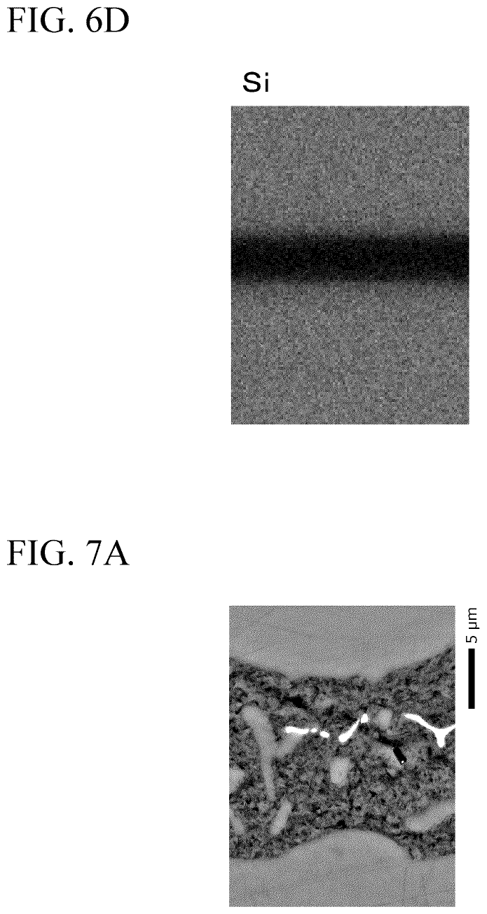

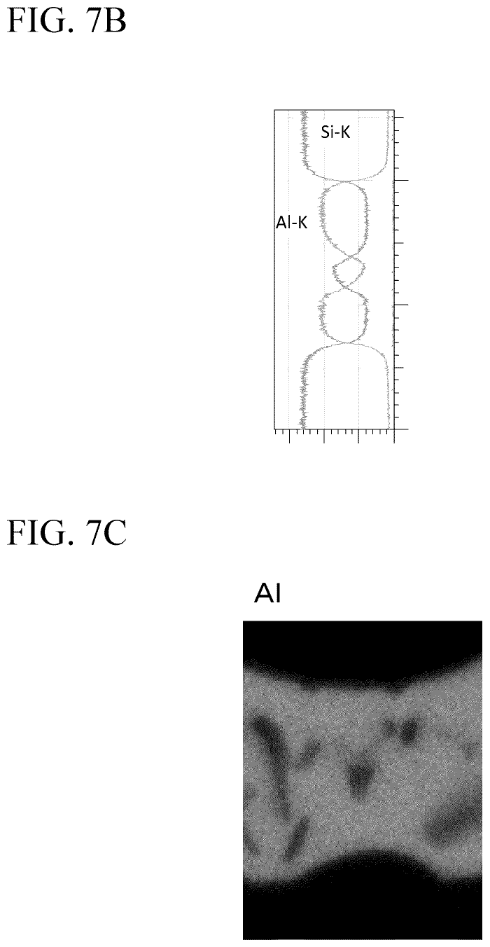

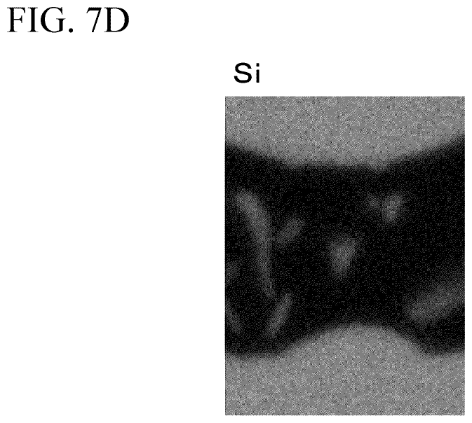

The observation results (SEM cross-sectional structure) and mapping results of Invention Example 1 are shown in FIG. 5A to FIG. 5C. The observation results (SEM cross-sectional structure), element line analysis results, and mapping results of Invention Example 6 are shown in FIG. 6A to FIG. 6D. The observation results (SEM cross-sectional structure), element line analysis results, and mapping results of Comparative Example 1 are shown in FIG. 7A to FIG. 7D.

### (Aspect Ratio of Si Phase)

The aspect ratios of the Si phases determined as described above were calculated using commercially available image analysis software (WIN Roof) and the average value thereof was determined.

The longest dimension of the observed Si phase was set as the major axis length, the longest dimension in the direction perpendicular to this major axis was set as the minor axis length, and the aspect ratio was set as the major axis length/minor axis length.

### (Number of Intersections Between Al Peaks and Si Peaks)

A cross-section along the lamination direction of the obtained silicon member was observed, SEM-EDS analysis (element line analysis) was performed on the bonding layer in the cross-section, a virtual line extending in the thickness direction of the bonding layer was drawn on the cross-section including the bonding layer, and the number of intersections between Al peaks and Si peaks on this extended virtual line was counted. The results of SEM-EDS line analysis of Invention Example 6 and Comparative Example 1 are each shown in FIG. 6B and FIG. 7B.

### (Appearance Observation)

The appearance of the obtained silicon member was visually observed and the presence or absence of the protrusion of the bonding material and the presence or absence of breaking were evaluated. Silicon members in which the protrusion of the bonding material and breaking were confirmed were marked as “D” (poor). Silicon members in which there was the protrusion of the bonding material but no breaking was confirmed were marked as “C” (fair). Silicon members in which the protrusion of the bonding material and breaking were not confirmed were marked as “B” (good).

### (Bonding Strength)

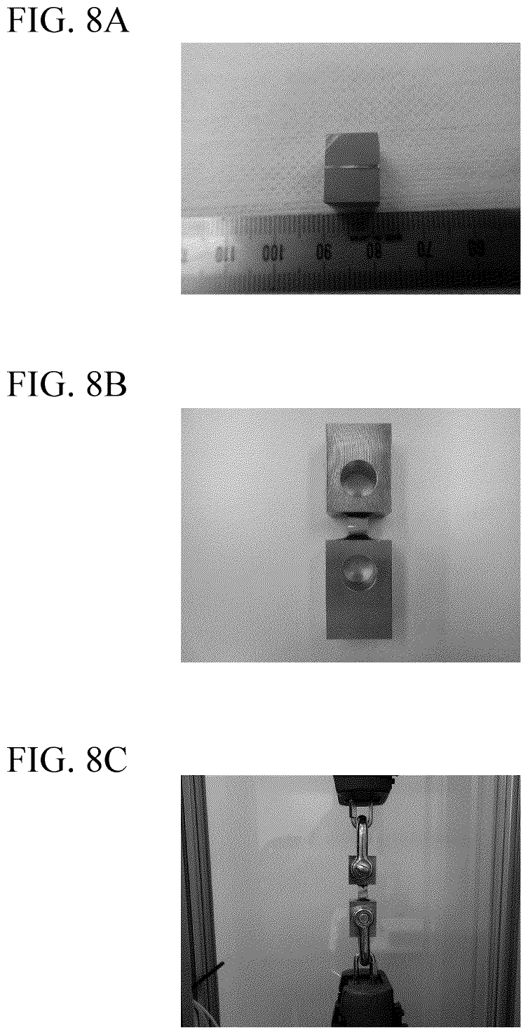

As shown in FIG. 8A to FIG. 8C, the obtained silicon member was cut into 10 mm squares and the surfaces of the plate-shaped members on the opposite side to the bonding surfaces were each bonded to a tensile test jig using adhesive. Then, the result was placed in a universal tensile tester and a tensile test was carried out at a speed of 0.1 mm/min. In a case where the bonding strength exceeded 15 MPa which was the bonding strength between the plate-shaped member and the tensile test jig due to the adhesive, the result was marked as “15 MPa or higher”.

### (Heat Resistance Test)

The obtained silicon member was held at 300° C. for 24 hours and then the appearance was visually observed to confirm the presence or absence of breaking or peeling. In addition, in a case where breaking or peeling was not visually observed, ultrasonic flaw inspection was carried out before and after heating at 300° C. As the confirmation results, silicon members that were confirmed to have breaking or peeling were marked as “D” (poor). Among the silicon members in which no breaking or peeling was confirmed, silicon members that had a change (change in the bonding rate) in the ultrasonic-detected image were marked as “B” (good). Silicon members that had no change (change in the bonding rate) in the ultrasonic-detected image were marked as “A” (excellent).

TABLE 1

| | | | | | Pressing and | | |
|---|---|---|---|---|---|---|---|
| | | Underlying | | | heating conditions | | |
| | | Al layer | Bonding material | | Holding | Holding | Pressing |
| | | Thickness | | Thickness | temperature | time | load |
| | | (μm) | Material | (μm) | (° C.) | (hours) | (MPa) |
| Invention | 1 | 1.0 | Al | 100 | 600 | 2 | 3 |
| Examples | 2 | 1.0 | Al | 100 | 550 | 2 | 3 |
| | 3 | 1.0 | Al-7.5 mass % Si | 20 | 600 | 2 | 3 |
| | 4 | None | Al-7.5 mass % Si | 20 | 600 | 2 | 3 |
| | 5 | None | Al-2.0 mass % Si | 20 | 600 | 2 | 3 |
| | 6 | 1.0 | None | — | 600 | 2 | 3 |
| | 7 | 1.0 | Al | 50 | 600 | 2 | 3 |
| Comparative | 1 | None | Al | 50 | 800 | 2 | — |
| Examples | 2 | None | Al | 50 | 800 | 2 | 3 |
| | 3 | None | Al | 50 | 600 | 2 | 3 |

TABLE 2

| | | Si phase | | | | | |
|---|---|---|---|---|---|---|---|
| | | | | Number of | | | |
| | | | | intersections | Evaluation | | |
| | | Area | | between Al | | Bonding | Heat |
| | | ratio | Aspect | peaks and Si | Appearance | strength | resistance |
| | | (%) | ratio | peaks | observation | (MPa) | evaluation |
| Invention | 1 | 0.0 | — | 2 | B | 15 or higher | A |
| Examples | 2 | 0.0 | — | 2 | B | 15 or higher | A |
| | 3 | 7.8 | 2.2 | 8 | B | 15 or higher | A |
| | 4 | 8.0 | 2.9 | 6 | B | 14.1 | B |
| | 5 | 2.4 | 2.4 | 4 | B | 15 or higher | A |
| | 6 | 0.0 | — | 2 | B | 15 or higher | A |
| | 7 | 0.0 | — | 2 | B | 15 or higher | A |
| Comparative | 1 | 13.0 | 4.5 | 10 | C | 4.1 | D |
| Examples | 2 | 14.0 | 4.3 | 12 | D | 5.3 | D |

| | |
|---|---|
| 3 | Bonding was not possible. |

In Comparative Example 1, Al layers were not formed on the bonding surfaces of the plate-shaped members, Al was used as the bonding material, and bonding was performed under conditions where pressure was not applied and a holding temperature was 800° C. As a result, the area ratio of the Si phases in the bonding layer was 13% and the aspect ratio of the Si phase was 4.5. In addition, the number of intersections between the Al peaks and the Si peaks was 10 and the number of Si phases present in the bonding layer was large. The bonding strength was 4.1 MPa which was low and breaking and peeling were confirmed after the heat resistance test. In addition, the protrusion of the bonding material was confirmed in the obtained silicon member.

In Comparative Example 2, Al layers were not formed on the bonding surfaces of the plate-shaped members, Al was used as the bonding material, and bonding was performed under conditions where a pressing load was 3 MPa and a holding temperature was 800° C. As a result, the area ratio of the Si phases in the bonding layer was 14% and the aspect ratio of the Si phase was 4.3. In addition, the number of intersections between the Al peaks and the Si peaks was 12 and the number of Si phases present in the bonding layer was large. The bonding strength was 5.3 MPa which was low and breaking and peeling were confirmed after the heat resistance test. In addition, the protrusion of the bonding material and breaking were confirmed in the obtained silicon member.

In Comparative Example 3, Al layers were not formed on the bonding surfaces of the plate-shaped members, Al was used as the bonding material, and bonding was attempted under conditions where a pressing load was 3 MPa and a holding temperature was 600° C., but it was not possible to bond the plate-shaped members together and it was not possible to obtain a silicon member.

In contrast, in Invention Example 1, Al layers were formed on the bonding surfaces of the plate-shaped members, Al was used as the bonding material, and bonding was performed under conditions where a pressing load was 3 MPa and a holding temperature was 600° C. As a result, the area ratio of the Si phases in the bonding layer was 0%, the number of intersections between the Al peaks and the Si peaks was 2, and Si phases were not present in the bonding layer. The bonding strength was 15 MPa or more which was high and no breaking or peeling was confirmed after the heat resistance test. In addition, no protrusion of the bonding material or the like was confirmed in the obtained silicon member. As shown in FIG. 5A to FIG. 5C, it was confirmed that Si phases were not present in the bonding layer. It is presumed that the diffusion of Si from the plate-shaped members to the bonding layer was suppressed by the Al layers.

In Invention Example 2, Al layers were formed on the bonding surfaces of the plate-shaped members, Al was used as the bonding material, and bonding was performed under conditions where a pressing load was 3 MPa and a holding temperature was 550° C. As a result, the area ratio of the Si phases in the bonding layer was 0%, the number of intersections between the Al peaks and the Si peaks was 2, and Si phases were not present in the bonding layer. The bonding strength was 15 MPa or more which was high, no breaking or peeling was confirmed after the heat resistance test, and no change (change in the bonding rate) was observed in the ultrasonic-detected image. In addition, no protrusion of the bonding material or the like was confirmed in the obtained silicon member.

In Invention Example 3, Al layers were formed on the bonding surfaces of the plate-shaped members, an Al-7.5 mass % Si alloy was used as the bonding material, and bonding was performed under conditions where a pressing load was 3 MPa and a holding temperature was 600° C. As a result, the area ratio of the Si phases in the bonding layer was 7.8% and the aspect ratio of the Si phase was 2.2. In addition, the number of intersections between the Al peaks and the Si peaks was 8. The bonding strength was 15 MPa or more which was high, no breaking or peeling was confirmed after the heat resistance test, and no change (change in the bonding rate) was observed in the ultrasonic-detected image. In addition, no protrusion of the bonding material or the like was confirmed in the obtained silicon member.

In Invention Example 4, Al layers were not formed on the bonding surfaces of the plate-shaped members, an Al-7.5 mass % Si alloy was used as the bonding material, and bonding was performed under conditions where a pressing load was 3 MPa and a holding temperature was 600° C. As a result, the area ratio of the Si phases in the bonding layer was 8.0% and the aspect ratio of the Si phase was 2.9. In addition, the number of intersections between the Al peaks and the Si peaks was 6. The bonding strength was 14.1 MPa which was relatively high and no breaking or peeling was confirmed after the heat resistance test. In addition, no protrusion of the bonding material or the like was confirmed in the obtained silicon member. Although a small amount of Si phases was present in the bonding layer, it was confirmed that the aspect ratio of the Si phase was sufficiently small.

In Invention Example 5, Al layers were not formed on the bonding surfaces of the plate-shaped members, an Al-2.0 mass % Si alloy was used as the bonding material, and bonding was performed under conditions where a pressing load was 3 MPa and a holding temperature was 600° C. As a result, the area ratio of the Si phases in the bonding layer was 2.4% and the aspect ratio of the Si phase was 2.4. In addition, the number of intersections between the Al peaks and the Si peaks was 4. The bonding strength was 15 MPa or more which was high, no breaking or peeling was confirmed after the heat resistance test, and no change (change in the bonding rate) was observed in the ultrasonic-detected image. In addition, no protrusion of the bonding material or the like was confirmed in the obtained silicon member.

In Invention Example 6, Al layers were formed on the bonding surfaces of the plate-shaped members, a bonding material was not used, and bonding was performed under conditions where a pressing load was 3 MPa and a holding temperature was 600° C. As a result, the area ratio of the Si phases in the bonding layer was 0%, the number of intersections between the Al peaks and the Si peaks was 2, and Si phases were not present in the bonding layer. The bonding strength was 15 MPa or more which was high, no breaking or peeling was confirmed after the heat resistance test, and no change (change in the bonding rate) was observed in the ultrasonic-detected image. In addition, no protrusion of the bonding material or the like was confirmed in the obtained silicon member. As shown in FIG. 6A to FIG. 6D, it was confirmed that no Si phases were present in the bonding layer.

In Invention Example 7, Al layers were formed on the bonding surfaces of the plate-shaped members, pure Al was used as the bonding material, and bonding was performed under conditions where a pressing load was 3 MPa and a holding temperature was 600° C. As a result, the area ratio of the Si phases in the bonding layer was 0%, the number of intersections between the Al peaks and the Si peaks was 2, and Si phases were not present in the bonding layer. The bonding strength was 15 MPa or more which was high, no breaking or peeling was confirmed after the heat resistance test, and no change (change in the bonding rate) was observed in the ultrasonic-detected image. In addition, no protrusion of the bonding material or the like was confirmed in the obtained silicon member.

As a result, it was confirmed from the Invention Examples that it is possible to provide a silicon member that has a sufficiently high bonding strength, excellent heat resistance, and is able to be used stably even in a high-temperature environment, and a method for producing the silicon member.

### INDUSTRIAL APPLICABILITY

The silicon member of the present embodiment is suitable for use as an electrode plate used in plasma processing apparatuses such as plasma etching apparatuses and plasma CVD apparatuses.

### REFERENCE SIGNS LIST

10 Silicon member (regenerated silicon electrode plate)
11 First plate-shaped member
12 Second plate-shaped member
20 Bonding layer
21 Al layer
25 Si phase

1. A silicon member comprising:
a plurality of plate-shaped members consisting of a Si-containing material,
wherein the plate-shaped members are bonded in a thickness direction, and
a bonding layer is formed between the plate-shaped members, and an area ratio of Si phases in the bonding layer is 12% or less.

2. The silicon member according to claim 1,
wherein an aspect ratio of the Si phase in the bonding layer is 3.0 or less.

3. The silicon member according to claim 1,
wherein the bonding layer includes Al or a metal containing Al.

4. The silicon member according to claim 3,
wherein the bonding layer consists of an Al—Si alloy in which an amount of Si is in a range of 0.5 mass % or more and 12.6 mass % or less.

5. The silicon member according to claim 3,
wherein, when line analysis is performed along a virtual line extending in the thickness direction of the silicon member, a number of intersections between Si peaks and Al peaks on the virtual line is 4 or less in the bonding layer.

6. A method for producing the silicon member according to claim 1, the method comprising:
a laminating step of arranging a bonding material between a plurality of the plate-shaped members and forming a laminate of the plurality of the plate-shaped members and the bonding material; and
a pressing and heating step of heating the laminate to a temperature lower than a liquidus temperature of the bonding material while pressing the laminate in a lamination direction.

7. The method for producing a silicon member according to claim 6,
wherein the bonding material includes Al or a metal containing Al.

8. The method for producing a silicon member according to claim 7,
wherein the bonding material consists of an Al—Si alloy in which an amount of Si is in a range of 0.5 mass % or more and 12.6 mass % or less.

9. The method for producing a silicon member according to claim 6, further comprising, before the laminating step:
an Al layer forming step of forming Al layers on bonding surfaces of the plate-shaped members,
wherein the laminating step includes arranging the plurality of the plate-shaped members such that the Al layers of the plate-shaped members oppose each other, arranging the bonding material to contact the opposing Al layers, and forming the laminate of the plurality of the plate-shaped members and the bonding material.

10. A method for producing the silicon member according to claim 2, the method comprising:
a laminating step of arranging a bonding material between a plurality of the plate-shaped members and forming a laminate of the plurality of the plate-shaped members and the bonding material; and
a pressing and heating step of heating the laminate to a temperature lower than a liquidus temperature of the bonding material while pressing the laminate in a lamination direction.

11. A method for producing the silicon member according to claim 3, the method comprising:
a laminating step of arranging a bonding material between a plurality of the plate-shaped members and forming a laminate of the plurality of the plate-shaped members and the bonding material; and
a pressing and heating step of heating the laminate to a temperature lower than a liquidus temperature of the bonding material while pressing the laminate in a lamination direction.

12. A method for producing the silicon member according to claim 4, the method comprising:
a laminating step of arranging a bonding material between a plurality of the plate-shaped members and forming a laminate of the plurality of the plate-shaped members and the bonding material; and
a pressing and heating step of heating the laminate to a temperature lower than a liquidus temperature of the bonding material while pressing the laminate in a lamination direction.

13. A method for producing the silicon member according to claim 5, the method comprising:
a laminating step of arranging a bonding material between a plurality of the plate-shaped members and forming a laminate of the plurality of the plate-shaped members and the bonding material; and
a pressing and heating step of heating the laminate to a temperature lower than a liquidus temperature of the bonding material while pressing the laminate in a lamination direction.

14. The method for producing a silicon member according to claim 10,
wherein the bonding material includes Al or a metal containing Al.

15. The method for producing a silicon member according to claim 11,
wherein the bonding material includes Al or a metal containing Al.

16. The method for producing a silicon member according to claim 12,
wherein the bonding material includes Al or a metal containing Al.

17. The method for producing a silicon member according to claim 13,
wherein the bonding material includes Al or a metal containing Al.

18. The method for producing a silicon member according to claim 10, further comprising, before the laminating step:
an Al layer forming step of forming Al layers on bonding surfaces of the plate-shaped members,
wherein the laminating step includes arranging the plurality of the plate-shaped members such that the Al layers of the plate-shaped members oppose each other, arranging the bonding material to contact the opposing Al layers, and forming the laminate of the plurality of the plate-shaped members and the bonding material.

19. The method for producing a silicon member according to claim 11, further comprising, before the laminating step:
an Al layer forming step of forming Al layers on bonding surfaces of the plate-shaped members,
wherein the laminating step includes arranging the plurality of the plate-shaped members such that the Al layers of the plate-shaped members oppose each other, arranging the bonding material to contact the opposing Al layers, and forming the laminate of the plurality of the plate-shaped members and the bonding material.

20. The method for producing a silicon member according to claim 12, further comprising, before the laminating step:
an Al layer forming step of forming Al layers on bonding surfaces of the plate-shaped members,
wherein the laminating step includes arranging the plurality of the plate-shaped members such that the Al layers of the plate-shaped members oppose each other, arranging the bonding material to contact the opposing Al layers, and forming the laminate of the plurality of the plate-shaped members and the bonding material.
